(19) United States
(12) Patent Application Publication
(10) Pub. No.: US 2010/0140590 A1
(43) Pub. Date: Jun. 10, 2010

(54) TRANSISTOR COMPRISING CARBON NANOTUBES FUNCTIONALIZED WITH A NON-FLUORO CONTAINING ELECTRON DEFICIENT OLEFIN OR ALKYNE

(75) Inventors: GRACIELA BEATRIZ BLANCHET, Boston, MA (US); Helen S. M. Lu, Wallingford, PA (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/633,207

(22) Filed: Dec. 8, 2009

Related U.S. Application Data
(60) Provisional application No. 61/121,202, filed on Dec. 10, 2008.

(51) Int. Cl. H01L 29/66; H01L 29/12; H01L 21/20

(52) U.S. Cl. 257/24; 257/9; 438/478; 257/E29.069; 257/E29.168; 257/E21.09; 977/742; 977/938

(57) ABSTRACT

The present invention is a transistor and a process for making the transistor in which the semiconductor component comprises at least one carbon nanotube functionalized by cycloaddition with a fluorinated olefin. Functionalization with the fluorinated olefin renders the carbon nanotube semiconducting.

### FIELD OF THE INVENTION

The present invention is a transistor and a process for making the transistor in which the semiconductor component comprises at least one carbon nanotube functionalized by cycloaddition with non-fluoro containing electron deficient olefin or non-fluoro electron deficient alkyne.

### TECHNICAL BACKGROUND

Park et al (Physical Review B 68,045429 (2003)) investigated stable adsorption geometries of fluorine atoms on a single-walled carbon nanotube using density-functional calculations.

Krusic et al (WO 2006/023921) describe carbon materials such as a fullerene molecule or a curved carbon nanostructure that is functionalized by addition chemistry performed on surface C—C double bond.

There exists a need for a transistor and a process for making the transistor in which the semiconductor component comprises at least one carbon nanotube functionalized with a non-fluoro containing electron deficient olefin or non-fluoro electron deficient alkyne.

### SUMMARY OF THE INVENTION

The present invention is a transistor comprising a semiconductor component comprising at least one carbon nanotube that has been functionalized by cycloaddition with a non-fluoro containing electron deficient olefin or non-fluoro electron deficient alkyne.

### BRIEF DESCRIPTION OF THE FIGURES

FIGS. 1A and B illustrate a field effect transistor.

FIG. 2 illustrates TGA analysis of the sample of Example 1.

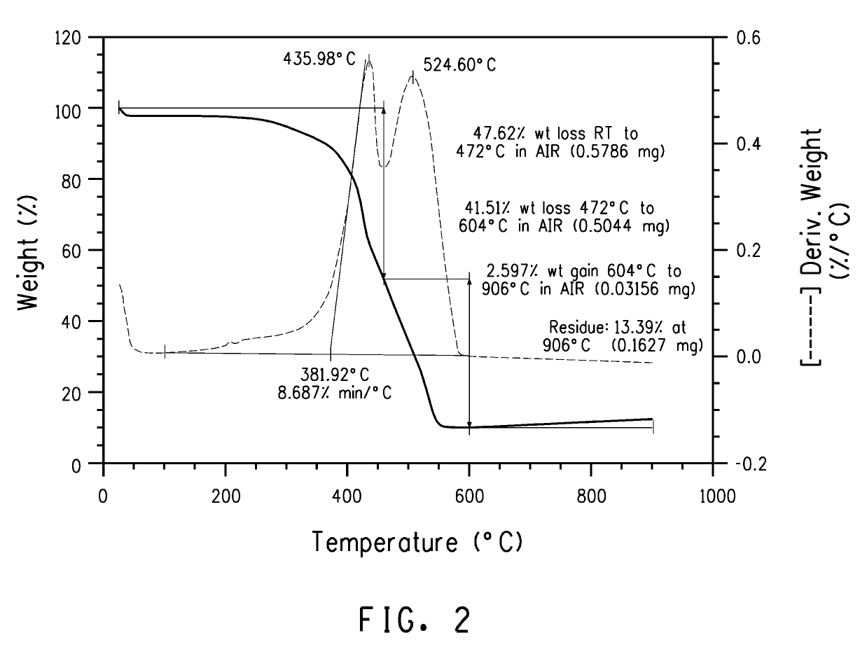

FIG. 3 illustrates a gate sweep of the sample of Example 1.

FIG. 4 illustrates a gate sweep of the sample of Example 2.

### DETAILED DESCRIPTION

The present invention is a transistor and a process for making a transistor comprising a semiconductor component comprising at least one carbon nanotube which has been functionalized by cycloaddition with a non-fluorinated electron deficient olefin or non-fluoro electron deficient alkyne. Functionalization with the non-fluoro containing electron deficient olefin or non-fluoro electron deficient alkyne renders the carbon nanotube semiconducting. As produced, carbon nanotubes are a mixture of metallic conducting nanotubes and semiconducting nanotubes. The semiconductor component of the transistor is a semiconducting material located between and in contact with the source and drain electrodes.

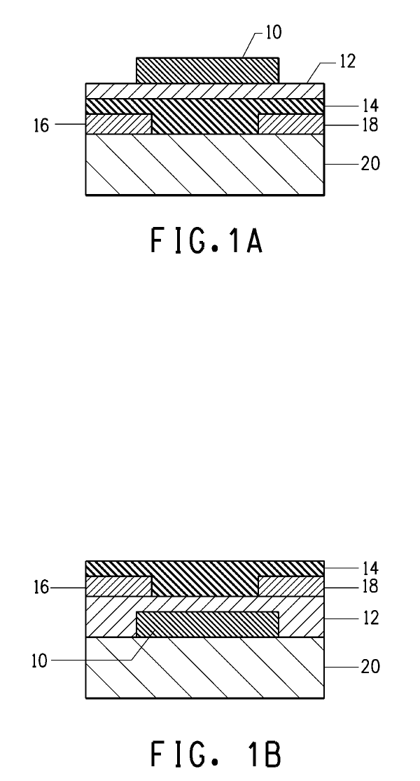

FIG. 1A illustrates a schematic of a top gate field effect transistor. A source electrode 16 and a drain electrode 18 are located on a semiconductor component 14 deposited on a substrate 20. A gate electrode 10 with a potential of approximately 0.1 volts creates an electric field which controls the charge carrier concentration in the semiconductor component and allows current to flow between the source and drain electrodes. The gate electrode is electrically insulated from the semiconductor component by a gate dielectric 12.

FIG. 1B illustrates a schematic of a bottom gate field effect transistor. A semiconductor component 14 is located on a source electrode 16 and a drain electrode 18. A gate electrode 10 with a potential of approximately 0.1 volts creates an electric field which controls the charge carrier concentration in the semiconductor component and allows current to flow between the source and drain electrodes. The gate electrode is deposited on a substrate 20. The gate electrode is electrically insulated from the semiconductor component by a gate dielectric 12.

In the present invention, carbon nanotubes are the semiconducting material of the semiconductor component. As produced, carbon nanotubes are a mixture of metallic conduction nanotubes and semiconducting nanotubes. Percolating arrays of mixtures of metallic and semiconducting nanotubes normally have the electrical conductivity dominated by the metallic-like tubes, which constitute about ⅔ of the carbon nanotube content, wherein the array exhibits metallic-like conductivity. Such arrays would not be suitable for fabrication of the semiconductor component of the transistor because the array is metallic rather than semiconducting. It has been found that functionalization of the carbon nanotubes by cycloaddition with non-fluoro containing electron deficient olefin or non-fluoro electron deficient alkyne allow the nanotubes to exhibit mostly semiconducting behavior. Thus, percolating arrays on functionalized carbon nanotubes are mostly semiconducting rather than metallic and may be used to fabricate semiconductor components of transistors. It is further possible to construct a transistor in which the semiconductor is a single carbon nanotube. Functionalization of a plurality of carbon nanotubes by cycloaddition with non-fluoro containing electron deficient olefin or non-fluoro containing electron deficient alkyne would insure that individual nanotube from a batch would be mostly semiconducting as well as functioning as the semiconductor component of the transistor.

Functionalization of carbon nanotubes by cycloaddition with non-fluoro containing electron deficient olefin or non-fluoro containing electron deficient alkyne convert metallic carbon nanotubes to mostly semiconducting nanotubes. It is believed that the functionalization process converts C═C (carbon carbon double bond) sp2 carbon centers into C—C (carbon carbon single bond) sp3 C—C centers, thereby converting metallic tubes to semiconducting tubes. In this invention, functionalization is achieved by addition chemistry performed on surface C—C double bond of a carbon nanostructure. This is referred to herein as a “2+2” cycloaddition The thermal 2+2 cycloaddition of olefins are not common (see e.g. Huisgen, R. in Acc. Chem. Res. 1977, 10, 117). The photolysis reaction is more common for the cycloaddition of olefins (see e.g. Mattes, S. L. et. al. in Acc. Chem. Res. 1982, 15, 80-86.).

In one embodiment of this invention, such a functionalization process may be performed in a reaction brought about by heating a carbon nanostructure material with an electron deficient olefin or non-fluoro electron deficient alkyne shown in Formula 1-5 listed below.

C(CN)2=C(R1)(R1) Formula 1

wherein
each R1 is independently selected from the group consisting of H, Cl, Br, nitrile, ester, carboxylic acid, sulfonic ester, sulfonic acid, sulfonamide, methyl, trifluoromethyl, branched or straight-chain alkyl, phenyl, aryl

C(CN)(R2)=C(CN)(R2) Formula 2

wherein

each R2 is independently selected from the group consisting of H, Cl, Br, nitrile, ester, carboxylic acid, sulfonic ester, sulfonic acid, sulfonamide, methyl, trifluoromethyl, branched or straight-chain alkyl, phenyl, aryl

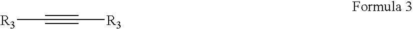

wherein
each R3 is independently selected from the group consisting of nitrile, ester, carboxylic acid, sulfonic ester, sulfonic acid, sulfonamide

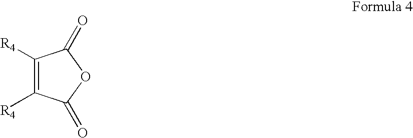

wherein
each R4 is independently selected from the group consisting H, Cl, Br, nitrile, ester, carboxylic acid, sulfonic ester, sulfonic acid, sulfonamide, methyl, trifluoromethyl, branched or straight-chain alkyl, phenyl, aryl

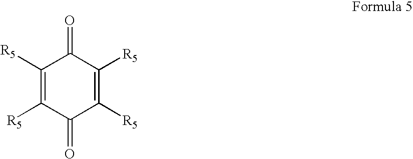

wherein
each R5 is independently selected from the group consisting H, Cl, Br, nitrile, ester, carboxylic acid, sulfonic ester, sulfonic acid, sulfonamide, methyl, trifluoromethyl, branched or straight-chain alkyl, phenyl, aryl

In one embodiment, the cycloaddition of carbon nanotube with a non-fluoro electron deficient olefin of Formula 1 will produce a functionalized carbon nanomaterial comprising n carbon atoms wherein m functional branches described generally by the formula

—C(CN)(CN)—C(−)(R1)(R1)- Formula 6

wherein
each R1 is independently selected from the group consisting of H, Cl, Br, nitrile, ester, carboxylic acid, sulfonic ester, sulfonic acid, sulfonamide, methyl, trifluoromethyl, branched or straight-chain alkyl, phenyl, aryl

are each covalently bonded to the carbon nanotube through formation of a 4-member ring with the unsaturated pi system of the carbon nanotube.

The bonds resulting from opening a C═C bond in both the nanotube and a compound of Formula I, the ensuing 2+2 cycloaddition, create the 4-member ring. As the ring itself is not shown in Formula 6, its presence is indicated by the incomplete bonds of the —C(CN)(CN) and C(−)(R1)(R1) residues shown therein.

In one embodiment, the cycloaddition of carbon nanotube with a non-fluoro electron deficient olefin of Formula 2 will produce a functionalized carbon nanomaterial comprising n carbon atoms wherein m functional branches described generally by the formula

—C(CN)(R2)-C(−)(CN)(R2)- Formula 7

wherein
each R2 is independently selected from the group consisting of H, Cl, Br, nitrile, ester, carboxylic acid, sulfonic ester, sulfonic acid, sulfonamide, methyl, trifluoromethyl, branched or straight-chain alkyl, phenyl, aryl

are each covalently bonded to the carbon nanotube through formation of a 4-member ring with the unsaturated pi system of the carbon nanotube.

The bonds resulting from opening a C═C bond in both the nanotube and a compound of Formula 2, the ensuing 2+2 cycloaddition, create the 4-member ring. As the ring itself is not shown in Formula 7, its presence is indicated by the incomplete bonds of the —C(CN)(R2) and C(−)(CN)(R2) residues shown therein.

In one embodiment, the cycloaddition of carbon nanotube with a non-fluoro electron deficient alkyne of Formula 3 will produce a functionalized carbon nanomaterial comprising n carbon atoms wherein m functional branches described generally by the formula

—C(R3)=C(−)(R3)- Formula 8

wherein

each R3 is independently selected from the group consisting of nitrile, ester, carboxylic acid, sulfonic ester, sulfonic acid, sulfonamide

are each covalently bonded to the carbon nanotube through formation of a 4-member ring with the unsaturated pi system of the carbon nanotube.

The bonds resulting from opening a C═C bond in the nanotube and a carbon carbon triple bond in a compound of Formula 3, the ensuing 2+2 cycloaddition, create the 4-member ring. As the ring itself is not shown in Formula 8, its presence is indicated by the incomplete bonds of the —C(R3) and C(−)(R3) residues shown therein.

In one embodiment, the cycloaddition of carbon nanotube with a non-fluoro electron deficient olefin of Formula 4 will produce a functionalized carbon nanomaterial comprising n carbon atoms wherein m functional branches described generally by the formula

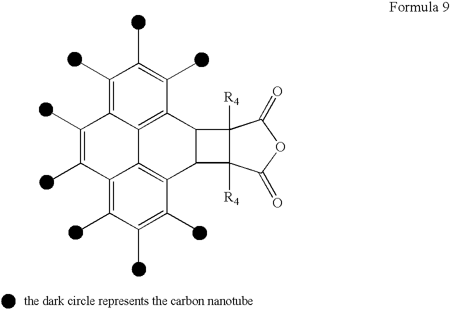

wherein

each R4 is independently selected from the group consisting H, Cl, Br, nitrile, ester, carboxylic acid, sulfonic ester, sulfonic acid, sulfonamide, methyl, trifluoromethyl, branched or straight-chain alkyl, phenyl, aryl

are each covalently bonded to the carbon nanotube through formation of a 4-member ring with the unsaturated pi system of the carbon nanotube.

In one embodiment, the cycloaddition of carbon nanotube with a non-fluoro electron deficient olefin of Formula 5 will produce a functionalized carbon nanomaterial comprising n carbon atoms wherein m functional branches described generally by the formula

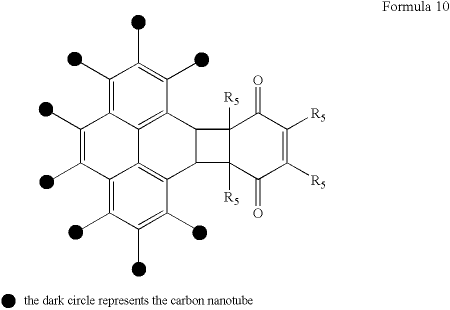

wherein
each R5 is independently selected from the group consisting H, Cl, Br, nitrile, ester, carboxylic acid, sulfonic ester, sulfonic acid, sulfonamide, methyl, trifluoromethyl, branched or straight-chain alkyl, phenyl, aryl

are each covalently bonded to the carbon nanotube through formation of a 4-member ring with the unsaturated pi system of the carbon nanotube.

Other suitable processes for performing an addition reaction on a carbon nanostructure include a photo-cycloaddition process such as described in Mattes, S. L. et. al. in Acc. Chem. Res. 1982, 15, 80-86.

In one embodiment of this invention, such a functionalization process may be performed in a reaction brought about by the photolysis of a carbon nanostructure material in the presence of an electron deficient olefin or non-fluoro electron deficient alkyne shown in Formula 1-5, to give a cycloadduct of the structure Formula 6.

In order to produce the functionalized carbon nanotubes, the nanotubes are contacted with non-fluoro containing electron deficient olefin or non-fluoro containing electron deficient alkyne, and the mixture of the non-fluoro containing electron deficient olefin or non-fluoro containing electron deficient alkyne and nanotubes is heated to around 215 C for 5 to 24 hours preferably 10 to 18 hours. The mixture is then dried.

Thermogravimetric analysis of mixtures of the functionalized carbon nanotubes wherein the functinalization is the cycloaddition of carbon nanotubes with a non-fluoro containing electron deficient olefin or a non-fluoro containing electron deficient alkyne can be performed and shows weight loss in the temperature range between 200 and 600 C. The dried carbon nanotubes may then be dispersed in a solvent such as o-dichlorobenzene, toluene, chloroform among others.

To fabricate a transistor of the present invention, the dispersion of functionalized carbon nanotubes in a solvent are deposited on a prefabricated partial transistor structure. The partial transistor structure contains other elements of the transistor such as pre-pattern source-drain structure and gate oxide. Standard transistors configurations are top gate and bottom gate. The partial transistor structure is fabricated on a substrate. Source and drain electrodes can be deposited on the substrate. The small space between the source and drain electrodes is referred to as the channel and it is the minimum amount required for the placement of the semiconducting material. The source and drain electrodes are electronic conductors and can be made by various methods such as evaporation, sputtering or by printing dispersions of metal particles in a solvent and drying the solvent. The dispersion of carbon nanotubes in a solvent is then deposited onto the source and drain electrodes. Spin coating, printing or ink jet printing may be used to deposit the semiconductor component of the dispersion of carbon nanotubes on the source and drain electrodes and then dried to allow evaporation of the solvent. The dried dispersion forms a percolating array of functionalized carbon nanotubes in the channel between and in contact with the source and drain electrodes. In top gate transistors, the source drain is defined on the device substrate and the semiconducting carbon nanotube applied directly on top. A gate dielectric which is an electrical insulator is then deposited on the semiconductor component. The gate dielectric may also be printed as a dispersion of metal oxide in a solvent. The gate electrode, a conductor, is then deposited on the gate dielectric. The gate electrode may also be a printed dispersion of metal particles in a solvent.

As shown in FIG. 1, the transistor may be fabricated such that the gate electrode is deposited directly on the substrate, or, as in a doped Si-wafer, the substrate is also the gate. The gate deposition is followed by the gate dielectric. The semiconductor component comprising the functionalized carbon nanotubes is then deposited on the gate dielectric and dried. Finally, the source and drain electrodes are deposited on the semiconductor component. Other arrangements of transistor components are also possible, but the semiconductor component is located between and in contact with the source and drain electrodes.

### Example 1

In the following examples 24 mg of the commercially purified HiPC® SWNTs were dried overnight at 250° C. at a pressure of <1 mbar. Tubes were then transferred into a 10 mL shaker tube for functionalization. 10 mg of Tetracyanoethylene (Molecular weight=128 g) ranging was dissolved in 2 ml of o-Dichlorobenzene by sonication and added to the shaker tubes containing the HiPco tubes. The tube was closed under nitrogen, chilled in dry ice for 30 minutes, and then evacuated to remove the N2. The reaction was conducted in at 215 C for 24 hours. After heating, the tube was evacuated through a cold trap. The carbon nanotube was filtered through 0.2 micron PTFE membranes and washed several times with organic solvents. The functionalized SWNTs were then dispersed in ODCB at a concentration of 300 mg/L and was horn sonicated at 22% of full power (750 watts) for 10 minutes.

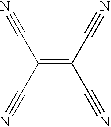

The chemical structure of TONE is shown above. The dispersions were found to be stable even after two weeks.

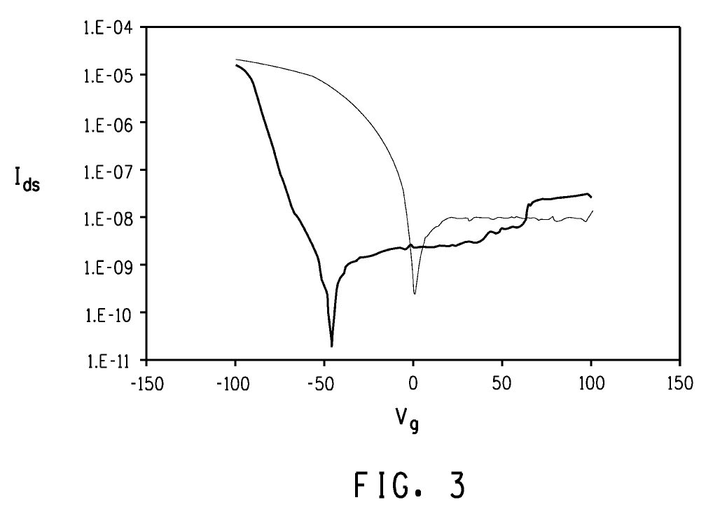

The dispersions were then coated onto a clean Si/SiO2 wafer with pre-patterned source drains. The oxide layer was 1500 A in thickness. The wafers were rinsed with acetone, followed by isopropyl alcohol and was finally rinsed with ultrapure water followed by drying with a nitrogen gun. The wafers were then plasma cleaned for 1 minute in an Argon atmosphere prior to the spinning of the carbon nanotube dispersion. Then the spin coating is done at 100 rpm for 60 sec. The wafer was then placed on the hotplate at 65° C. for around 30 minutes. The wafer was then placed in Nitrogen glove box for electrical characterization. The electrical properties were measured using a standard Agilent unit 4155C, California City, Calif. The gate sweep of a device with W/L=200/20 in example 1 is shown in FIG. 3. The source drain voltage was set to −0.1 Volts and the gate voltage was swept from 100 V to −100V as shown. The linear mobility (forward) was calculated to be 850 cm²/Vsec and the on/off ratio was 6.47×10⁵.

### Example 2

In the following examples 24 mg of the commercially purified HiPC® SWNTs were dried overnight at 250° C. at a pressure of <1 mbar. Tubes were then transferred into a 10 mL shaker tube for functionalization. 24 mg Tetracyanoethylene (Molecular weight=128 g) were dissolved in 2 ml of o-Dichlorobenzene by sonication and added to the shaker tubes containing the HiPco tubes. The tube was closed under nitrogen, chilled in dry ice for 30 minutes, and then evacuated to remove the N2. The reaction was conducted in at 215 C for 24 hours. After heating, the tube was evacuated through a cold trap. The carbon nanotube was filtered through 0.2 micron PTFE membranes and washed several times with organic solvents. The functionalized SWNTs were then dispersed in ODCB at a concentration of 300 mg/L and was horn sonicated at 22% of full power (750 watts) for 10 minutes.

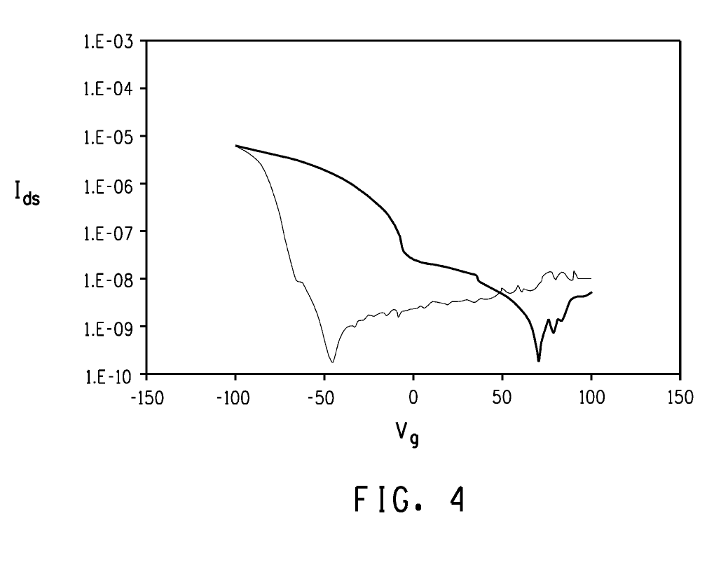

The electrical properties were measured using a standard Agilent unit 4155C, California City, Calif. The gate sweep of a device with W/L=200/20 as shown in FIG. 4. The source drain voltage was set to 0.1 Volts and the gate voltage was swept from 100 V to −100V as shown. The linear mobility was calculated to be 12.3 cm²/Vsec and the on/off ratio was 1.87×10⁶

What is claimed is:

1. A carbon nanotube comprising functionalization by cycloaddition with a non-fluoro containing electron deficient olefin or a non-fluoro electron deficient alkyne.

2. A transistor comprising:
a) a semiconductor component comprising at least one carbon nanotube of claim 1;
b) a source electrode;
c) a drain electrode;
d) a gate dielectric; and
e) a gate electrode.

3. An electronic device comprising:
a) A first electrode;
b) a semiconductor component comprising a percolating array of carbon nanotubes of claim 1 in contact with the first electrode; and
c) a second electrode in contact with the semiconductor component.

4. An electronic device comprising:
d) a first electrode;
e) a semiconductor component comprising at least one carbon nanotube of claim 1 in contact with the first electrode; and
f) a second electrode in contact with the semiconductor component.

5. A transistor comprising:
a) a semiconductor component comprising a percolating array of carbon nanotubes of claim 1;
b) a source electrode;
c) a drain electrode;
d) a gate dielectric; and
e) a gate electrode.

6. A process comprising:
a) providing a substrate comprising at least one electrode; and
b) depositing a percolating array of carbon nanotubes of claim 1 on the substrate.

7. A process comprising:
a) providing a substrate comprising at least one electrode; and
b) depositing at least one carbon nanotube of claim 1 on the substrate.

8. A process comprising:
a) providing a substrate;
b) depositing a percolating array of carbon nanotubes of claim 1 on the substrate; and
c) depositing at least one electrode on the percolating array of carbon nanotubes.

9. A process comprising:
a) providing a substrate;
b) depositing at least carbon nanotubes of claim 1 on the substrate; and
c) depositing at least one electrode on the array of carbon nanotubes.
